(19) United States
(12) Patent Application Publication
(10) Pub. No.: US 2026/0283021 A1
(43) Pub. Date: Sep. 17, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Itsuki Matsuo, Nakatsu Oita (JP); Toshihiro Tsujimura, Tokyo Japan (JP); Eitaro Miyake, Tachikawa Tokyo (JP); Yoshinari Tamura, Yokohama Kanagawa (JP)

(21) Appl. No.: 19/355,332

(22) Filed: Oct. 10, 2025

(30) Foreign Application Priority Data
Mar. 17, 2025 (JP) 2025-042914

(51) Int. Cl. H10W 90/00

(52) U.S. Cl. CPC H10W 90/00; H10W 90/756

(57) ABSTRACT

According to one embodiment, a semiconductor device includes a substrate including a first electrode that is provided on a first surface of the substrate toward a first direction, a first semiconductor chip provided on the first surface and including a first pad electrically coupled to the first electrode, a second semiconductor chip provided on the first surface and including a second pad electrically coupled to the first electrode, a resin provided on the first surface of the substrate to cover the first semiconductor chip and the second semiconductor chip, and a conductor having a bent portion projecting upward from the first electrode. One end of the conductor is coupled to the first electrode. The conductor is isolated from other conductors excluding the first electrode. The bent portion is covered with the resin.

### CROSS-REFERENCE TO RELATED APPLICATION

This application is based upon and claims the benefit of priority from Japanese Patent Application No. 2025-042914, filed Mar. 17, 2025, the entire contents of which are incorporated herein by reference.

### FIELD

Embodiments described herein relate generally to a semiconductor device.

### BACKGROUND

A semiconductor device having a variety of package structures is proposed for size reduction and high functionality.

### BRIEF DESCRIPTION OF THE DRAWINGS

FIG. 1 is a schematic diagram illustrating an apparatus including a semiconductor device according to a first embodiment.

FIG. 2 is a schematic perspective view illustrating a structure of the semiconductor device according to the first embodiment.

FIG. 3 is a schematic plan view showing a structure of the upper surface side of the semiconductor device according to the first embodiment.

FIG. 4 is a schematic plan view showing a structure of the lower surface side of the semiconductor device according to the first embodiment.

FIG. 5 is a schematic cross-sectional view showing a cross-sectional structure of the semiconductor device according to the first embodiment.

FIG. 6 is a circuit diagram illustrating an example of a circuit configuration of the semiconductor device according to the first embodiment.

FIG. 7 is a cross-sectional view showing an example in which the upper surface of the semiconductor device according to the first embodiment is ground to expose a bonding wire.

FIG. 8 is a schematic perspective view illustrating a structure of a semiconductor device according to a second embodiment.

FIG. 9 is a schematic plan view showing a structure of the upper surface side of the semiconductor device according to the second embodiment.

FIG. 10 is a schematic cross-sectional view showing a cross-sectional structure of the semiconductor device according to the second embodiment.

FIG. 11 is a cross-sectional view showing an example in which the upper surface of the semiconductor device according to the second embodiment is ground to expose a conductor.

FIG. 12 is a schematic perspective view illustrating a structure of a semiconductor device according to a third embodiment.

FIG. 13 is a schematic cross-sectional view showing a cross-sectional structure of the semiconductor device according to the third embodiment.

### DETAILED DESCRIPTION

In general, according to one embodiment, a semiconductor device includes a substrate including a first electrode that is provided on a first surface of the substrate toward a first direction, a first semiconductor chip provided on the first surface and including a first pad electrically coupled to the first electrode, a second semiconductor chip provided on the first surface and including a second pad electrically coupled to the first electrode, a resin provided on the first surface of the substrate to cover the first semiconductor chip and the second semiconductor chip, and a conductor having a bent portion projecting upward from the first electrode. One end of the conductor is coupled to the first electrode. The conductor is isolated from other conductors excluding the first electrode. The bent portion is covered with the resin.

Embodiments will be described below with reference to the drawings. In the following description, components having the same function and configuration are denoted by common reference symbols. In order to distinguish a plurality of components with common reference symbols, different suffixes are attached to the common reference symbols. Unless a plurality of components are particularly distinguished, only common reference symbols are attached to the components and no suffixes are attached thereto. The suffixes are not limited to subscripts or superscripts, but include a lowercase alphabet added to the end of a reference symbol, an index representing an array, and the like.

In the present specification and the claims, "coupling" of a first element to a second element includes the fact that the first element is coupled to the second element directly or via an element that is constantly or selectively conductive.

### 1. First Embodiment

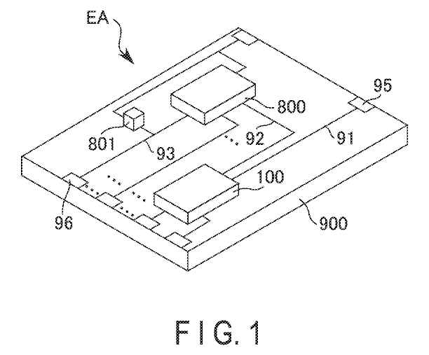

A first embodiment will be described with reference to FIGS. 1-7. A semiconductor device according to the first embodiment is a photo relay device. The semiconductor device is not limited to a photo relay device. The first embodiment can be applied to a semiconductor device including electrodes (terminals) not exposed to the outside of a package.

### 1.1 Overall Configuration

First, an example of an apparatus including a semiconductor device 100 according to the first embodiment will be described with reference to FIG. 1. FIG. 1 is a schematic diagram illustrating the apparatus including a semiconductor device 100.

As shown in FIG. 1, the semiconductor device 100 is provided in an electrical apparatus EA. The electrical apparatus EA is an industrial machine, a power converter, a vehicle on-board unit, an home electrical appliance, sound equipment, a video device, a communication device, a computer system, or the like.

The semiconductor device 100 is mounted on a module substrate (also referred to as a motherboard or a printed circuit board) 900 together with one or more other devices (e.g., other semiconductor devices or electronic components) 800 and 801.

The module substrate 900 includes a plurality of interconnects 91, 92, and 93 and a plurality of terminals 95 and 96.

The interconnects 91, 92, and 93 are provided on the surface of the module substrate 900 or inside the module substrate 900. Each of the interconnects 91, 92, and 93 is coupled to one or more corresponding terminals out of the terminals (connectors, sockets, or slots) 95 and 96 or coupled to one of the devices 100, 800, and 801 on the module substrate 900. Each of the terminals 95 and 96 is supplied with its corresponding one of various voltages (e.g., power supply voltages or ground voltages) or signals.

The semiconductor device 100 is coupled to the interconnects 91 and 92 of the module substrate 900. For example, the semiconductor device 100 is coupled to the terminal 95 via the interconnect 91 or to the semiconductor device 800 (or the electronic components 801) via the interconnect 92 on the module substrate 900.

The semiconductor device 800 includes, for example, a semiconductor integrated circuit or a discrete device. Note that the semiconductor device 800 may be a device that is modularized by a plurality of chips and a plurality of passive elements. The electronic component 801 is a passive element, such as a capacitor, an inductor, a resistor, and a switch

The semiconductor device 800 and the electronic component 801 are coupled to the terminal 96 via the interconnect 93 or coupled to each other via another interconnect.

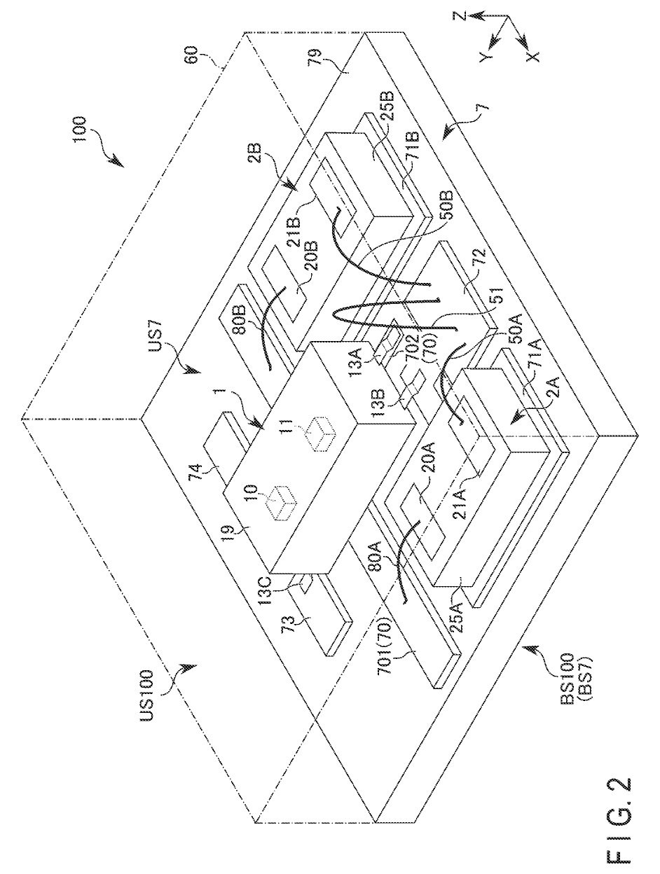

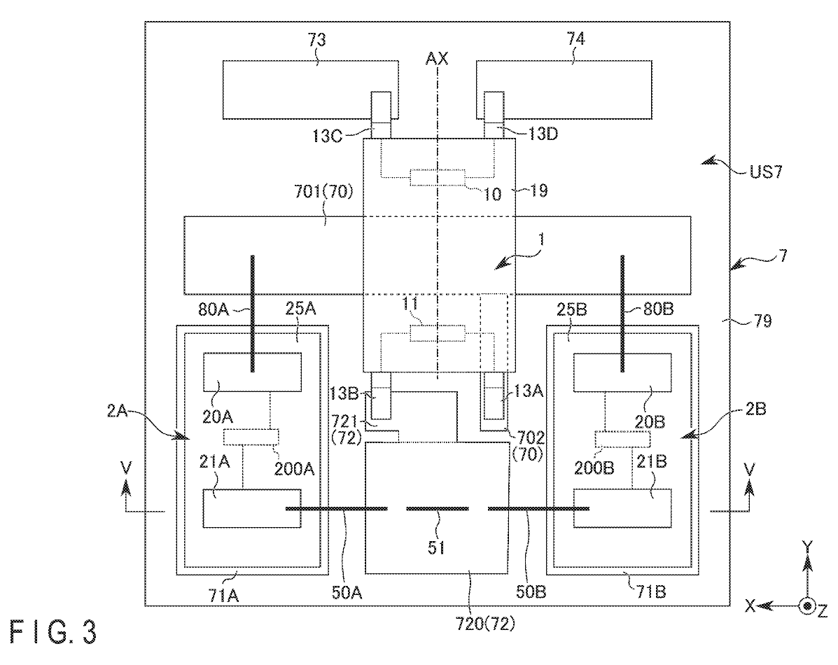

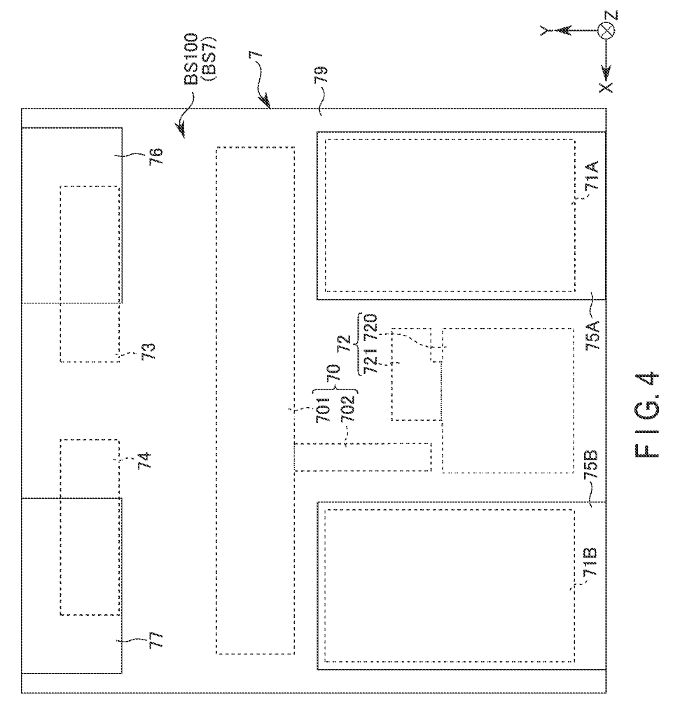

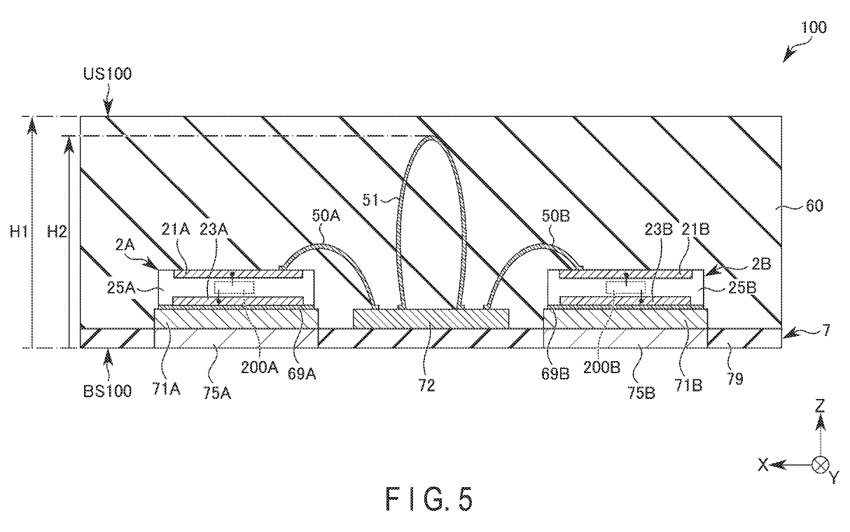

An example of the internal configuration of the semiconductor device 100 of the first embodiment will be described below with reference to FIGS. 2-5. FIG. 2 is a schematic perspective view illustrating a structure of the semiconductor device 100. In FIG. 2, a package member 60 is shown as a frame with a one-dot-one-dash line in order to ensure the visibility of the interior of the package member 60. FIG. 3 is a schematic plan view showing a structure of the upper surface side of the semiconductor device 100. FIG. 4 is a schematic plan view showing a structure of the lower surface side of the semiconductor device 100. FIG. 5 is a schematic cross-sectional view showing a cross-sectional structure of the semiconductor device 100. FIG. 5 shows a cross-section taken along line V-V of FIG. 3.

In the following description, the direction parallel to a package substrate (also referred to as a substrate) 7 of the semiconductor device 100 is defined as an X direction. The direction parallel to the package substrate 7 and intersecting the X direction is defined as a Y direction. The direction perpendicular to the surface of the package substrate 7 and intersecting the X and Y directions is defined as a Z direction (or a "longitudinal direction"). In the Z direction, the side toward the package substrate 7 from the package member 60 is described as a "lower side" and its opposite side is described as an "upper side."

As shown in FIGS. 2-5, the semiconductor device 100 of the first embodiment includes one semiconductor package (also referred to as a package device) 1 and two semiconductor chips 2 (2A and 2B). The semiconductor device 100 is a surface mount device (SMD).

The semiconductor package 1 and semiconductor chips 2A and 2B are provided on the upper surface US7 of the package substrate 7. The semiconductor package 1 and semiconductor chips 2A and 2B are covered with a package member (also referred to as an insulating resin, an encapsulating resin, a molding resin, or a resin) 60 on the upper surface US7 of the package substrate 7. For example, the semiconductor chips 2A and 2B are arranged side by side in the X direction.

The semiconductor device 100 has a package-in-package (PiP) structure with respect to the semiconductor package 1.

The package substrate 7 includes a substrate member 79, a lead frame 70, a plurality of die pads 71A and 71B, a plurality of electrodes 72, 73, and 74 and a plurality of terminals 75A, 75B, 76, and 77.

The substrate member 79 is an insulator. For example, the substrate member 79 is an insulating organic material (e.g., polyimide) or an insulating ceramic. The substrate member 79 supports the lead frame 70, die pads 71A and 71B, electrodes 72, 73, and 74, and terminals 75A, 75B, 76, and 77 in the package substrate 7.

The lead frame 70, die pads 71A and 71B, electrodes 72, 73, and 74, and terminals 75A, 75B, 76, and 77 are isolated from each other.

The lead frame 70, die pads 71A and 71B, electrodes 72, 73, and 74, and terminals 75A, 75B, 76, and 77 contain copper (Cu), for example.

As shown in FIGS. 2 and 3, the lead frame 70 is located on the upper surface of the substrate member 79, that is, on the upper surface US7 of the package substrate 7 and in a region between a region where the electrodes 73 and 74 are provided and a region where the electrode 72 is provided.

As shown in FIG. 2, the upper surface of the lead frame 70 is exposed from the upper surface of the substrate member 79 (the upper surface US7 of the package substrate 7).

As shown in FIG. 3, the lead frame 70 includes a first lead portion 701 and a second lead portion 702. The two lead portions 701 and 702 are a single continuous conductor.

The first lead portion 701 has a rectangular (linear) shape extending in the X direction when viewed from the Z direction. The second lead portion 702 has a rectangular (linear) shape extending in the Y direction when viewed from the Z direction. The lead frame 70 has a T-shape (or a shape similar to a T-shape) when viewed from the Z-direction.

The first lead portion 701 extends from one end side of the substrate member 79 (package substrate 7) in the X direction toward the other end side thereof. One end of the first lead portion 701 in the X direction is located near one end of the substrate member 79 in the X direction. The other end of the first lead portion 701 in the X direction is located near the other end of the substrate member 79 in the X direction. The first lead portion 701 passes through a region below the semiconductor package 1 in the Z direction. The first lead portion 701 partially overlaps the semiconductor package 1 when viewed from the Z direction. For example, the first lead portion 701 is not in direct contact with the semiconductor package 1.

One end of the second lead portion 702 is coupled to the first lead portion 701. The second lead portion 702 passes through a region below the semiconductor package 1 in the Z direction and extends from the first lead portion 701 toward a coupling terminal 13A of the semiconductor package 1. The second lead portion 702 extends in the Y direction.

The lead frame 70 is also referred to as a lead portion, a pad, a conductive portion, an interconnect, or a coupling member.

As shown in FIG. 2, the upper surfaces of the two die pads 71 (71A and 71B) are exposed from the upper surface of the substrate member 79 (the upper surface US7 of the package substrate 7). The die pad 71A is isolated from the die pad 71B. The die pad 71 functions as a mounting portion of the semiconductor chip 2 and also functions as an electrical coupling member (electrode or pad) to the semiconductor chip 2. For example, the die pad 71 (71A and 71B) is also referred to as a base portion, a mount portion, a stage, or an electrode.

As shown in FIG. 3, the two die pads 71A and 71B are arranged side by side in the X direction with the electrode 72 therebetween. The die pads 71A and 71B are adjacent to the first lead portion 701 in the Y direction.

For example, the two die pads 71A and 71B extend in the Y direction and are located in the package substrate 7 symmetrically with a line passing through the center of the package substrate 7 (substrate member 79) as a symmetry axis.

The electrode 72 is provided on one end side (lower side of the sheet of FIG. 3) of the upper surface US7 of the package substrate 7 (the upper surface of the substrate member 79) in the Y direction. The electrode 72 is located side by side with the semiconductor package 1 in the Y direction when viewed from the Z direction. The electrode 72 is provided in a region between the die pads 71A and 71B in the X direction. As shown in FIG. 2, the upper surface of the electrode 72 is exposed from the upper surface of the substrate member 79 (the upper surface US7 of the package substrate 7).

As shown in FIG. 3, the electrode 72 includes two portions (also referred to as electrode portions) 720 and 721. The portion 720 has a rectangular planar shape as viewed from the Z direction. The portion 721 has a hook-like (L-shaped) planar shape as viewed from the Z-direction. The portions 720 and 721 are a single continuous conductor.

The portion 720 is provided between the two die pads 71 in the X direction.

The portion 721 is adjacent to the second lead portion 702 in the X direction. However, the portion 721 (and portion 720) is isolated from the second lead portion 702.

The electrodes 73 and 74 are provided on the other end side (the upper side of the sheet of FIG. 3) of the upper surface US7 of the package substrate 7 (the upper surface of the substrate member 79) in the Y direction. In the Y direction, the electrodes 73 and 74 are opposed to the electrode 72 with the lead frame 70 therebetween.

As shown in FIG. 2, the upper surfaces of the electrodes 73 and 74 are exposed from the upper surface of the substrate member 79 (the upper surface US7 of the package substrate 7). As shown in FIG. 3, the electrodes 73 and 74 have a rectangular planar shape when viewed from the Z direction.

The electrode 73 is isolated from the electrode 74 in the X direction. That is, the electrodes 73 and 74 are arranged side by side in the X direction.

Note that the electrodes 72, 73, and 74 are also referred to as lead portions, pads, conductive portions, or coupling members.

The spaces between the lead frame 70, die pad 71, and electrodes 72, 73, and 74 may be filled with the package member 60 or the substrate member 79.

As shown in FIG. 4, in the first embodiment, the terminals (hereinafter referred to as external coupling terminals) 75 (75A and 75B), 76, and 77 are provided alongside the lower surface BS7 of the package substrate 7. In other words, the external coupling terminals 75, 76, and 77 are provided on the lower surface BS100 of the semiconductor device 100. The external coupling terminals 75, 76, and 77 are terminals for coupling the semiconductor device 100 to other devices (or interconnects on the module substrate, or terminals of the module substrate). For example, the external coupling terminals 75, 76 and 77 are provided in the opening of substrate member 79.

The external coupling terminal 75A is provided to overlap with the die pad 71A in the Z direction. The external coupling terminal 75B is provided to overlap with the die pad 71B in the Z direction.

The external coupling terminal 75 has a rectangular planar shape when viewed from the Z direction.

The external coupling terminal 75 is exposed from the lower surface of the substrate member 79 (the lower surface BS7 of the package substrate 7, i.e., the lower surface BS100 of semiconductor device 100). The side surface of the external coupling terminal 75 may be exposed from the side surface of the package substrate 7 (semiconductor device 100) so that the external coupling terminal 75 has a wettable flank (WF) structure.

As shown in FIG. 5, the external coupling terminal 75 is directly coupled (is brought into contact) with the die pad 71. However, the external coupling terminal 75 may be electrically coupled to the die pad 71 alongside the upper surface US7 of the package substrate 7 via a contact portion provided in the substrate member 79. The external coupling terminal 75 may be a single conductor that is continuous with the die pad 71.

As shown in FIG. 4, the external coupling terminal 76 is provided alongside the lower surface BS7 of the package substrate 7 (the lower surface BS100 of the semiconductor device 100) so as to partially overlap with the electrode 73 in the Z direction.

Like the external coupling terminal 75, the external coupling terminal 76 is directly coupled (is brought into contact) with the electrode 73. However, the external coupling terminal 76 may be electrically coupled to the electrode 73 alongside the upper surface US7 of the package substrate 7 via a contact portion (not shown) provided in the substrate member 79. The external coupling terminal 76 may be a single conductor that is continuous with the electrode 73.

The external coupling terminal 77 is provided alongside the lower surface BS7 (the lower surface BS100 of the semiconductor device 100) of the package substrate 7 so as to partially overlap with the electrode 74 in the Z direction.

Like the external coupling terminal 75, the external coupling terminal 77 is directly coupled (is brought into contact) with the electrode 74. However, the external coupling terminal 77 may be electrically coupled to the electrode 74 alongside the upper surface US7 of the package substrate 7 via a contact portion (not shown) provided in the substrate member 79. The external coupling terminal 77 may be a single conductor that is continuous with the electrode 74.

The external coupling terminals 76 and 77 each have a rectangular planar shape when viewed from the Z direction.

The external coupling terminals 76 and 77 are exposed from the lower surface of the substrate member 79 (the lower surface BS7 of package substrate 7, i.e., the lower surface BS100 of semiconductor device 100). The side surfaces of the external coupling terminals 76 and 77 may be exposed from the side surface of the package substrate 7 (semiconductor device 100) so that the external coupling terminals 76 and 77 have a WF structure.

The lead frame 70, die pad 71, and electrodes 72, 73, and 74 alongside the upper surface US7 of the package substrate 7 may be referred to as front side electrodes (or front side pads), and the external coupling terminals 75, 76, and 77 alongside the lower surface BS7 of the package substrate 7 may be referred to as back side electrodes (or back side pads).

As shown in FIGS. 2 and 3, the semiconductor package 1 is provided on the upper surface US7 of the package substrate 7. The semiconductor package 1 is located above the lead frame 70 in the Z direction. The semiconductor package 1 is located in a region between the two semiconductor chips 2A and 2B arranged in the X direction. A portion of the semiconductor package 1 is sandwiched between the two semiconductor chips 2A and 2B in the X direction. For example, the semiconductor package 1 is located in a central region of the upper surface US7 of the package substrate 7.

The semiconductor package 1 includes a first circuit portion 10 and a second circuit portion 11 in a package member 19. For example, the package member 19 is an insulator including a light shielding layer.

As shown in FIG. 3, the semiconductor package 1 includes four coupling terminals (also referred to as coupling nodes or lead portions) 13A, 13B, 13C, and 13D which are coupled to the first circuit portion 10 and second circuit portion 11. The coupling terminals 13A and 13B are provided on one end side of the semiconductor package 1 in the Y direction. The coupling terminals 13C and 13D are provided on the other end side thereof in the Y direction.

The coupling terminal 13A is coupled to the second lead portion 702 of the lead frame 70 via, for example, a conductive member (not shown) such as a conductive paste and solder.

The coupling terminal 13B is coupled to a portion 721 of the electrode 72 via the conductive member.

The coupling terminal 13C is coupled to the electrode 73 via the conductive member.

The coupling terminal 13D is coupled to the electrode 74 via the conductive member.

The semiconductor chip 2A is provided on the die pad 71A on the upper surface US7 of the package substrate 7. The semiconductor chip 2B is provided on the die pad 71B on the upper surface US7 of the package substrate 7.

The two semiconductor chips 2A and 2B partially sandwich the semiconductor package 1 in the X direction. For example, the semiconductor chips 2A and 2B are arranged on the upper surface US7 of the package substrate 7 in a symmetrical layout with a line AX passing through the center of the semiconductor package 1 in its XY plane (a line passing through the center of the package substrate 7 in its XY plane) as a symmetry axis. The line AX as the symmetry axis is along the Y direction.

For example, the semiconductor chip 2A is provided in a region surrounded by the lead frame 70 and the electrode 72 in a region between the line AX and one end of the package substrate 7 in the X direction. For example, the semiconductor chip 2B is provided in a region surrounded by the lead frame 70 and the electrode 72 in a region between the line AX and the other end of the package substrate 7 in the X direction.

For example, the semiconductor chips 2A and 2B are provided in a region between the first lead portion 701 of the lead frame 70 and one end of the package substrate 7 in the Y direction (an end portion where the electrode 72 is provided).

The semiconductor chips 2A and 2B are bare chips (bare dies) of semiconductor elements. The semiconductor chips 2A and 2B are sealed with the package member 60 on the package substrate 7.

For example, the size of the semiconductor chips 2A and 2B is smaller than that of the semiconductor package 1. For example, the dimensions (thickness or height) of the semiconductor chips 2A and 2B in the Z direction are smaller than those of the semiconductor package 1 in the Z direction.

The semiconductor chip 2A includes a chip member 25A including an element portion 200A and an interconnect layer (e.g., a multilayer interconnect structure). The semiconductor chip 2A has a plurality of pads (also referred to as coupling terminals, coupling nodes, or electrodes) 20A, 21A, and 23A in the chip member 25A. The pads 20A, 21A, and 23A are coupled to the element portion 200A in the chip member 25A. An element is formed on a semiconductor substrate in the element portion 200A.

The pads 20A and 21A are provided on the upper surface side of the chip member 25A. The pad 23A is provided on the lower surface side of the chip member 25A. The lower surface of the chip member 25A is a surface alongside the die pad 71A. The upper surface of the chip member 25A is opposed to the lower surface of the chip member 25A in the Z direction.

As shown in FIG. 2, the pad 20A is electrically coupled to the first lead portion 701 of the lead frame 70 by a bonding wire 80A. For example, the pad 20A is electrically coupled to a portion of the first lead portion 701 on its one end side in the X direction.

As shown in FIGS. 2, 3, and 5, the pad 21A is electrically coupled to the portion 720 of the electrode 72 by a bonding wire 50A, for example. Thus, the pad 21A is electrically coupled to the semiconductor package 1 via the electrode 72. Note that the conductor which electrically couples the pad 21A and the portion 720 of the electrode 72 is not limited to the bonding wire 50A. A plurality of bonding wires 50A may be provided.

The pad 23A is electrically coupled to the die pad 71A via a conductive member 69A such as solder and conductive paste. Accordingly, the pad 23A is electrically coupled to the external coupling terminal 75A via the die pad 71A.

As shown in FIG. 3, the semiconductor chip 2B includes a chip member 25B having an element portion 200B (and an interconnect layer). The semiconductor chip 2B includes a plurality of pads (also referred to as coupling nodes, coupling terminals, or electrodes) 20B, 21B, and 23B in the chip member 25B. In the chip member 25B, the pads 20B, 21B, and 23B are coupled to the element portion 200B. An element is formed on the semiconductor substrate in the element portion 200B.

The pads 20B and 21B are provided on the upper surface side of the chip member 25B. The pad 23B is provided on the lower surface side of the chip member 25B. The lower surface of the chip member 25B is a surface alongside the die pad 71B. The upper surface of the chip member 25B is opposed to the lower surface of the chip member 25B in the Z direction.

As shown in FIG. 2, like the pad 20A, the pad 20B is electrically coupled to the first lead portion 701 of the lead frame 70 via a bonding wire 80B. For example, the pad 20B is electrically coupled to a portion of the first lead portion 701 on the other end side in the X direction.

As shown in FIGS. 2, 3, and 5, the pad 21B is electrically coupled to a portion 720 of the electrode 72 via a bonding wire 50B. That is, the pad 21B is electrically coupled to the pad 21A via the electrode 72. The pad 21B is also electrically coupled to the semiconductor package 1 via the electrode 72. Note that a conductor which electrically couples the pad 21B and the portion 720 of the electrode 72 is not limited to the bonding wire 50B. A plurality of bonding wires 50B may be provided.

The pad 23B is electrically coupled to the die pad 71B via a conductive member 69B. Thus, the pad 23B is electrically coupled to the external coupling terminal 75B via the die pad 71B.

A bonding wire 51 projects upward from the electrode 72. Note that two or more bonding wires 51 may be provided. The bonding wire 51 may be another conductor. Both ends of the bonding wire 51 are coupled (brought into contact) with the electrode 72. That is, both ends of the bonding wire 51 are in contact with the same electrode. The bonding wire 51 is provided to bend upward of the electrode 72. That is, the bonding wire 51 has a portion coupled to the electrode 72 and a portion that bends upward of the electrode 72. The bonding wire 51 is not in contact with (is not coupled with) a conductive member other than the electrode 72. In other words, the bonding wire 51 is located apart from a conductive member other than the electrode 72. The bonding wire 51 functions as an external extraction electrode of the electrode 72 (pads 21A and 21B) for use in product characterization and the like. As shown in FIG. 5, the height H2 from the lower surface BS100 of the semiconductor device 100 to the upper end of the bonding wire 51 (which is also referred to simply as "height position H2 of the upper end of the bonding wire 51") is higher than any of the other conductive members (lead frames, pads, electrodes, terminals, bonding wires, etc.) in the semiconductor device 100 and lower than the height H1 from the lower surface BS100 of the semiconductor device 100 to the upper surface US100 thereof (which is also referred to simply as "height position H1 of the upper surface US100"). In the example shown in FIG. 5, among the other conductive members, the upper ends of the bonding wires 50A and 50B are the highest. In this case, the height position H2 of the upper end of the bonding wire 51 is higher than that of the upper ends of the bonding wires 50A and 50B.

### 1.2 Circuit Configuration of Semiconductor Device

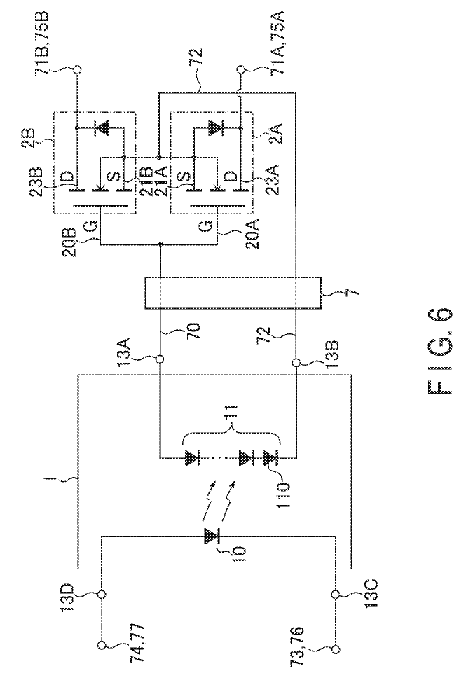

An example of a circuit configuration of the semiconductor device 100 according to the first embodiment will be described below with reference to FIG. 6. FIG. 6 is a circuit diagram illustrating the example of a circuit configuration of the semiconductor device 100.

For example, the semiconductor device 100 of the first embodiment is a photo relay.

In this example, the semiconductor package 1 is a photocoupler (optical coupling device). The photocoupler includes an optical coupling insulation circuit.

Each of the semiconductor chips 2 is a semiconductor element. The semiconductor chips 2 are, for example, field effect transistors. As a more specific example, the semiconductor chips 2 are MOS transistors (e.g., power MOS transistors).

The semiconductor package 1 and the semiconductor chips 2 are electrically coupled to each other via the lead frame 70 and the electrode 72.

As shown in FIG. 6, the photocoupler 1 includes a light emitting element 10 and a light receiving element 11 as components of the optical coupling insulation circuit.

The light emitting element 10 is, for example, a light emitting diode (LED).

One node (e.g., cathode) of the light emitting element 10 is coupled to the coupling terminal 13C. The other node (e.g., anode) of the light emitting element 10 is coupled to the coupling terminal 13D. The coupling terminals 13C and 13D are input terminals of the photocoupler 1. An input voltage for controlling the photo relay 100 is applied to the coupling terminals 13C and 13D through the electrodes 73 and 74 and external coupling terminals 76 and 77 of the package substrate 7.

The light receiving element 11 is, for example, a photodiode array. The light receiving element 11 includes, for example, several to several tens of photodiodes 110 coupled in series. The light receiving element 11 may be a phototransistor.

One node (e.g., cathode) of the light receiving element 11 is coupled to the coupling terminal 13B. The other node (e.g., anode) of the light receiving element 11 is coupled to the coupling terminal 13A. The coupling terminals 13A and 13B are output terminals of the photocoupler 1.

The MOS transistors 2A and 2B are, for example, enhancement n-channel MOS transistors. The MOS transistors 2A and 2B are used to control the transfer of signals of the photo relay 100. The signals transmitted by the photo relay 100 may be DC signals or AC signals.

The gate (G) of the MOS transistor 2A is coupled to the pad 20A. The source (S) of the MOS transistor 2A is coupled to the pad 21A. The drain (D) of the MOS transistor 2A is coupled to the pad 23A.

The gate (G) of the MOS transistor 2B is coupled to the pad 20B. The source (S) of the MOS transistor 2B is coupled to the pad 21B. The drain (D) of the MOS transistor 2B is coupled to the pad 23B.

The gates of the MOS transistors 2A and 2B are commonly coupled to the anode 13A of the light receiving element 11 via the bonding wire 80 and the lead frame 70.

The sources of the MOS transistors 2A and 2B are commonly coupled to the cathode 13B of the light receiving element 11 via the electrode 72.

The drain of the MOS transistor 2A is coupled to the external coupling terminal 75A via the die pad 71A. The drain of the MOS transistor 2B is coupled to the external coupling terminal 75B via the die pad 71B.

The external coupling terminals 76 and 77 serve as input terminals of a photo relay as the semiconductor device 100 of the first embodiment. The external coupling terminals 75A and 75B serve as output terminals of a photo relay as the semiconductor device 100 of the first embodiment.

In the photocoupler 1, a light emitting element 10 emits light in response to the voltages applied to the external coupling terminals 76 and 77. Thus, the light emitting element 10 converts an electrical signal into an optical signal.

The light receiving element 11 receives an optical signal from the light emitting element 10. The light receiving element 11 generates voltages of 7V to a dozen or so volts in response to the received optical signal. In this manner, the light receiving element 11 converts the optical signal into an electrical signal. The light receiving element 11 applies the generated voltage, as a gate voltage of the MOS transistor 2, to the MOS transistor 2 through the lead frame 70 and the bonding wire 80.

Each of the MOS transistors 2A and 2B is driven in response to the voltage generated by the light receiving element 11. Each of the MOS transistors 2A and 2B outputs current in response to the voltage applied to the gate thereof. If, therefore, the MOS transistors 2A and 2B are in the ON state, the photo relay 100 transmits a signal.

In the photocoupler 1, when the light emitting element 10 is turned off, the output of voltage from the light receiving element 11 is stopped. Accordingly, the MOS transistors 2A and 2B are turned off. As a result, the output terminals 75A and 75B of the photo relay 100 are brought into an electrically nonconductive state. Therefore, the photo relay 100 does not transmit a signal when the MOS transistors 2A and 2B are in the OFF state.

As described above, the photo relay as the semiconductor device 100 of the first embodiment is operated.

Note that the semiconductor device 100 of the first embodiment is not limited to a photo relay.

The semiconductor package 1 is not limited to a photocoupler. For example, the semiconductor package 1 may be a discrete device such as a transistor or a semiconductor circuit such as an integrated circuit.

The semiconductor element of the semiconductor chip 2 is not limited to a field effect transistor. For example, the semiconductor chip 2 may include a bipolar transistor or an insulated gate bipolar transistor (IGBT). The semiconductor chip 2 may be a semiconductor circuit.

### 1.3 Specific Example of Cross-Section of Semiconductor Device in Evaluation of Characteristics

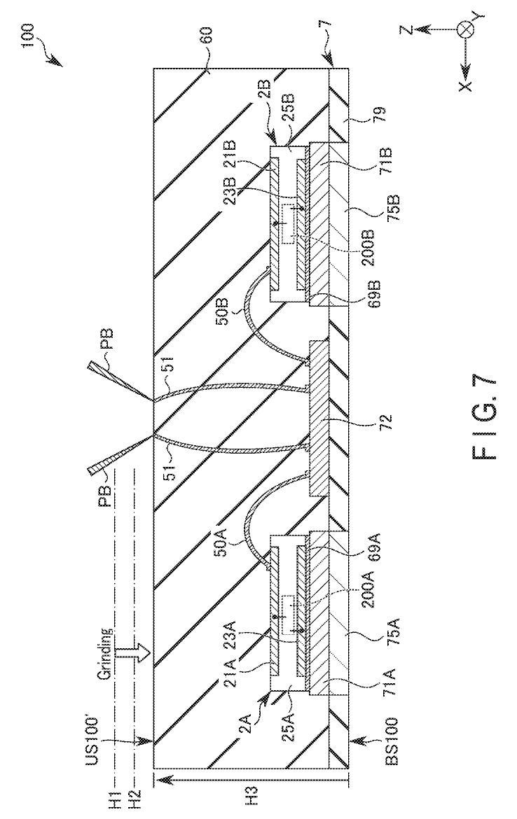

A specific example of a cross-section of the semiconductor device in evaluation of characteristics will be described below with reference to FIG. 7. FIG. 7 is a cross-sectional view of the semiconductor device 100 of the first embodiment, showing an example in which the upper surface S100 of the semiconductor device is ground to expose the bonding wire 51.

For example, the pad 21A of the semiconductor chip 2A and the pad 21B of the semiconductor chip 2B are coupled to each other via the electrode 72. That is, the semiconductor chips 2A and 2B are coupled by a source common. None of the pads 21A and 21B and electrode 72 is exposed to the outside of the package member 60 (semiconductor device 100). The semiconductor device 100 is not provided with the external coupling terminals coupled to the pads 21A and 21B and the electrode 72. Therefore, for example, when the characteristics of the semiconductor chip 2 alone are evaluated, the probe PB of a characteristics checker cannot be applied directly to the pad 21 or the electrode 72. In this case, it is necessary to remove the package member 60 to expose a portion to be an electrode, which takes a lot of trouble.

On the other hand, the structure of the semiconductor device 100 of the first embodiment makes it possible to provide the bonding wire 51 on the electrode 72. The height position H2 of the upper end of the bonding wire 51 can be made higher than other conductive members and lower than the height position H1 of the upper surface US100 of the semiconductor device 100. If the height position H2 of the upper end of the bonding wire 51 is made lower than the height position H1 of the upper surface US100 of the semiconductor device 100, the bonding wire 51 is not exposed to the outside (to the upper surface US100) of the package member 60. In other words, in the bonding wire 51, a wire portion farthest from the electrode 72 or a wire portion located uppermost is sealed by the package member 60. Thus, when the semiconductor device 100 is normally used as a product, the bonding wire 51 does not affect the electrical coupling of the electrodes 72, i.e., pads 21A and 21B. In addition, the height position H2 of the upper end of the bonding wire 51 is made higher than any of the other conductive members, the package member 60 (upper surface US100 of the semiconductor device 100) can be ground to expose the bonding wire 51 only.

As shown in FIG. 7, for example, the package member 60 (the upper surface US100 of the semiconductor device 100) is ground in the characteristics evaluation. The ground upper surface of the semiconductor device 100 is defined as an upper surface US100'. The height H3 from the lower surface BS100 of the semiconductor device 100 to the upper surface US100' thereof (also referred to simply as the "height position of the upper surface US100') is higher than that of other conductive members (e.g., bonding wires 50A and 50B) and lower than the height position H2 of the bonding wire 51. Thus, only the bonding wire 51 is exposed to the upper surface US100'. If, in this state, the probe PB of a characteristics checker is applied to the exposed bonding wire 51, for example, the characteristics of only the semiconductor chip 2 can be evaluated.

As described above, the configuration of the semiconductor device 100 according to the first embodiment makes it possible to evaluate the characteristics relatively easily using an electrode not exposed to the outside of the package. In the first embodiment, the bonding wire 51 is provided on the electrode 72, but it may be provided on another electrode. For example, it may be provided on the pads 21A and 21B.

### 2. Second Embodiment

Next is a description of a second embodiment. As the second embodiment, a configuration of the semiconductor device 100 which differs from that in the first embodiment will be mainly described below.

### 2.1 Configuration of Semiconductor Device

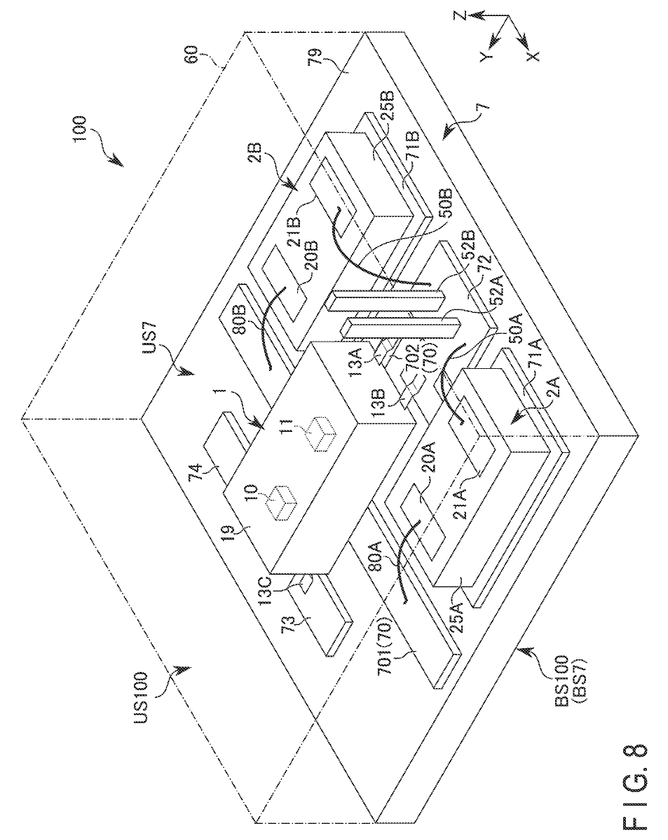

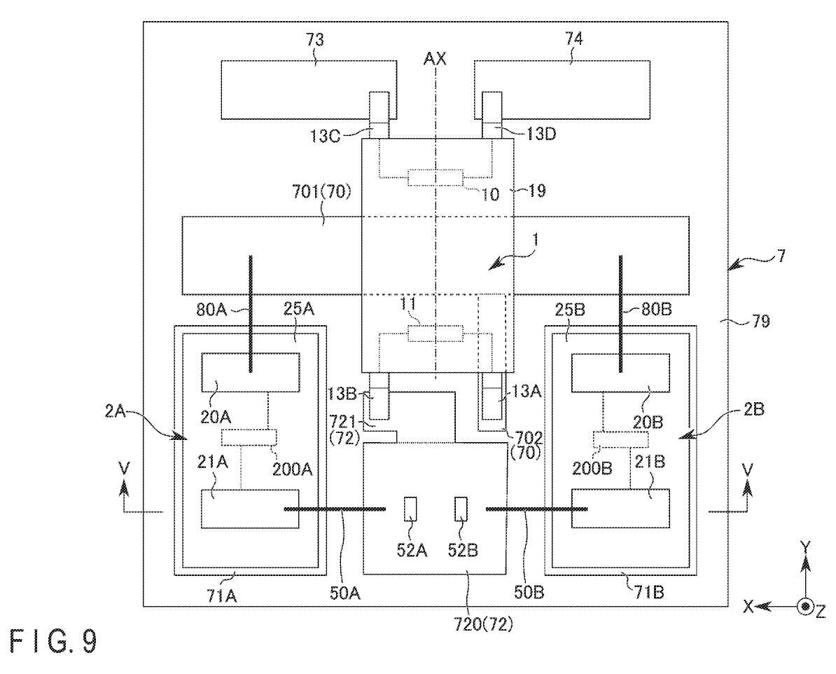

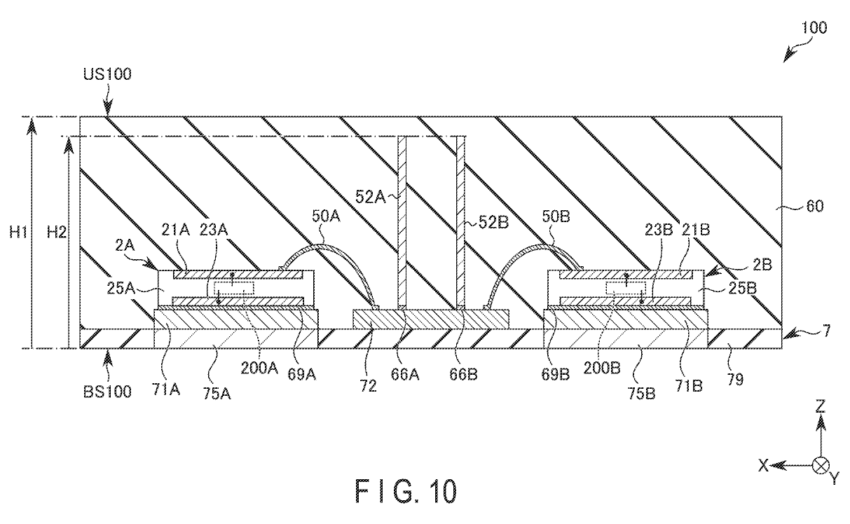

An example of the internal configuration of the semiconductor device 100 according to the second embodiment will be described with reference to FIGS. 8-10. FIG. 8 is a schematic perspective view illustrating the structure of the semiconductor device 100 of the second embodiment. Note that in FIG. 8, the package member 60 is shown as a frame with a one-dot-one-dash line in order to ensure the visibility of the interior of the package member 60. FIG. 9 is a schematic plan view showing a structure of the upper surface side of the semiconductor device 100 of the second embodiment. FIG. 10 is a schematic cross-sectional view showing a cross-sectional structure of the semiconductor device 100 of the second embodiment. In FIG. 10, a cross-section taken along line V-V of FIG. 9 is shown.

As shown in FIGS. 8-10, the semiconductor device 100 is provided with two conductors 52 (52A and 52B) instead of the bonding wire 51. The conductors 52 function as external extraction electrodes of the electrode 72 (pads 21A and 21B) for use in evaluation of product characteristics and the like. The other configurations are similar to those of the semiconductor device 100 of the first embodiment. Note that the number of conductors 52 provided on the electrodes 72 is not limited to two. It may be one or may be three or more.

The conductors 52A and 52B are arranged side by side on the electrode 72, for example, in the X direction. The conductors 52A and 52B are provided so as to project upward from the upper side of the electrode 72 and are not in contact with any conductive members other than the electrode 72. In other words, the conductors 52A and 52B are located apart from other conductor members other than the electrode 72. The arrangement of the conductors 52A and 52B on the electrode 72 is arbitrary. The conductors 52A and 52B contain copper, for example. The conductors 52A and 52B have a square prism shape extending in the Z direction. Note that the shape of the conductors 52A and 52B is not limited. They may have a columnar shape or other shapes. In addition, the upper ends of the conductors 52A and 52B may be coupled to each other by another conductor.

As shown in FIG. 10, one end (lower end) of the conductor 52A in the Z direction is coupled to the electrode 72 via a conductive member 66A, such as solder and conductive paste. Similarly, one end (lower end) of the conductor 52B in the Z direction is coupled to the electrode 72 via a conductive member 66B, such as solder and conductive paste.

In the second embodiment, the height from the lower surface BS100 of the semiconductor device 100 to the upper end of the conductor 52 (also referred to simply as "the height position of the upper end of the conductor 52") is defined as H2. As in the first embodiment, the height position H2 of the upper end of the conductor 52 is higher than any of the other conductive members (lead frames, pads, electrodes, terminals, bonding wires, etc.) in the semiconductor device 100 and lower than the height position H1 of the upper surface US100. In the example shown in FIG. 10, among the other conductive members, the upper ends of the bonding wires 50A and 50B are the highest. In this case, the height position H2 of the upper end of the conductor 52 is higher than the height position of the upper ends of the bonding wires 50A and 50B. In FIG. 10, at least the upper ends of the conductors 52A and 52B are covered with the package member 60.

### 2.2 Specific Example of Cross-section of Semiconductor Device in Evaluation of Characteristics

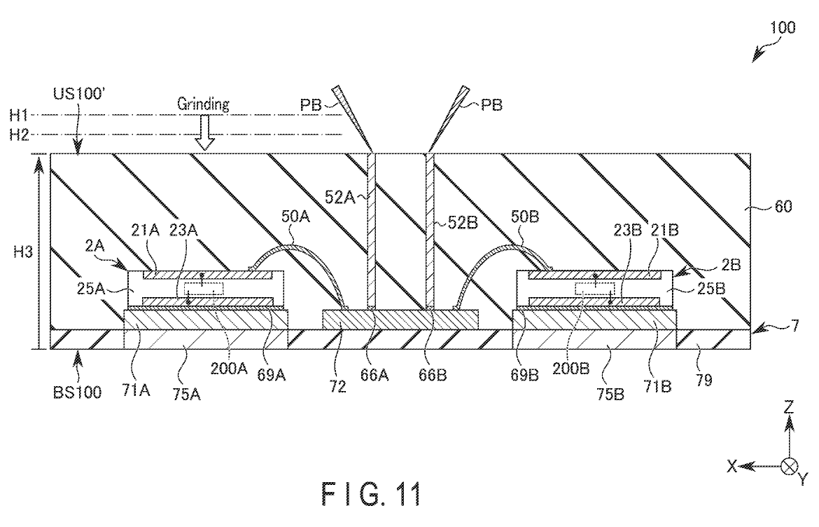

A specific example of a cross-section of the semiconductor device in evaluation of characteristics will be described below with reference to FIG. 11. FIG. 11 is a cross-sectional view of the semiconductor device 100 of the second embodiment, showing an example in which the upper surface S100 of the semiconductor device is ground to expose the conductor 52.

As shown in FIG. 11, for example, the upper surface US100 (package member 60) of the semiconductor device 100 is ground in the characteristics evaluation. The ground upper surface of the semiconductor device 100 is defined as an upper surface US100'. The height H3 from the lower surface BS100 of the semiconductor device 100 to the upper surface US100' thereof (also referred to simply as the "height position of the upper surface US100') is higher than that of other conductive members (e.g., bonding wires 50A and 50B) and lower than the height position H2 of the conductor 52. Thus, only the conductor 52 is exposed to the upper surface US100'. If, in this state, the probe PB of a characteristics checker is applied to the exposed conductor 52, for example, the characteristics of only the semiconductor chip 2 can be evaluated.

The configuration according to the second embodiment brings about the same advantageous effects as those of the first embodiment.

Furthermore, in the configuration according to the second embodiment, the conductor 52 is provided in place of the bonding wire 51. Thus, at the time of sealing by the package member 60, a deformation of the conductor 52 due to the pouring of the package member 60 can be suppressed.

### 3. Third Embodiment

Next is a description of a third embodiment. As the third embodiment, a configuration of the semiconductor device 100 which differs from those of the first and second embodiments will be mainly described below.

### 3.1 Configuration of Semiconductor Device

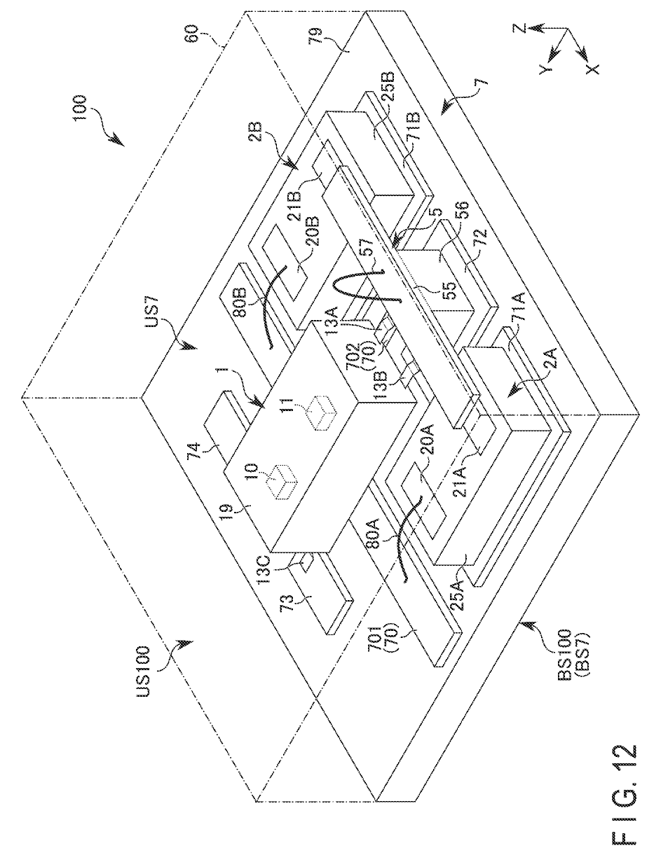

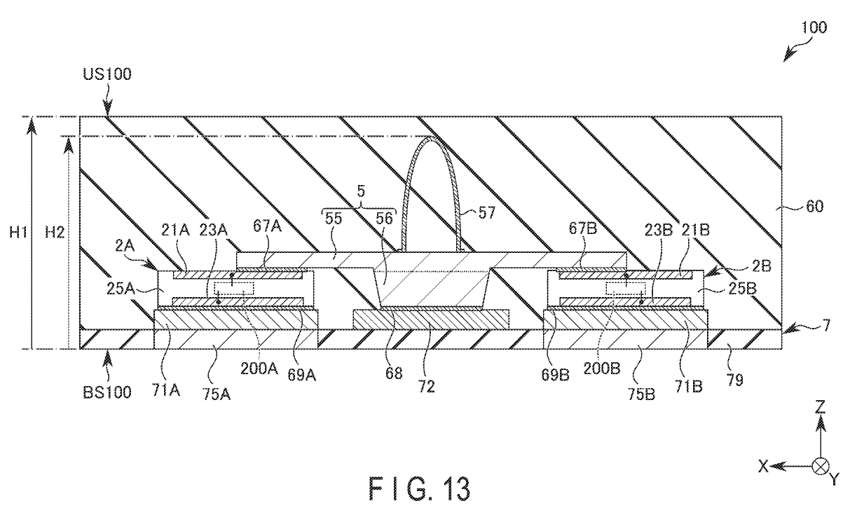

An example of the internal configuration of the semiconductor device 100 according to the third embodiment will be described with reference to FIGS. 12 and 13. FIG. 12 is a schematic perspective view illustrating the structure of the semiconductor device 100 of the third embodiment. Note that in FIG. 12, the package member 60 is shown as a frame with a one-dot-one-dash line in order to ensure the visibility of the interior of the package member 60. FIG. 13 is a schematic cross-sectional view showing a cross-sectional structure of the semiconductor device 100 of the third embodiment.

As shown in FIGS. 12 and 13, in the semiconductor device 100, a connector 5 for connecting the pads 21A and 21B and the electrode 72 is provided instead of the bonding wires 50A and 50B.

The connector 5 includes a first portion 55 and a second portion 56. The first portion 55 is one conductor continuous with the second portion 56. The connector 5 contains copper.

The first portion 55 extends along the X-Y plane. The first portion 55 extends over two semiconductor chips 2A and 2B. The first portion 55 is coupled to the pad 21A of the semiconductor chip 2A and the pad 21B of the semiconductor chip 2B by conductive members 67A and 67B, such as solder or conductive paste.

The second portion 56 is provided between the first portion 55 and the electrode 72. The second portion 56 is coupled to the electrode 72 by a conductive member 68.

The connector 5 has, for example, the T-shape in a cross-section viewed from the Y direction.

A bonding wire 57 is provided to project upward from the first portion 55 of the connector 5. Two or more bonding wires 57 may be provided. The bonding wire 57 may be another conductor. Both ends of the bonding wire 57 are coupled to (are in contact with) the first portion 55. That is, both ends of the bonding wire 57 are in contact with the same electrode. The bonding wire 57 is provided to bend upward of the first portion 55. That is, the bonding wire 57 includes a coupling portion with the first portion 55 and a portion that bends (curves) upward of the first portion 55. The bonding wire 57 is not in contact with any conductive member other than the first portion 55. In other words, the bonding wire 57 is located apart from conductive members other than the electrode 72. The bonding wire 57 functions as an external extraction electrode of the electrode 72 (pads 21A and 21B) for use in evaluation of product characteristics and the like.

As shown in FIG. 13, in the third embodiment, the height from the lower surface BS100 of the semiconductor device 100 to the upper end of the bonding wire 57 (also referred to simply as "the height position of the upper end of the bonding wire 57") is defined as H2. As in the first embodiment, the height position H2 of the upper end of the bonding wire 57 is higher than any other conductive member (e.g., connector 5) in the semiconductor device 100 and lower than the height position H1 of the upper surface US100.

The configuration according to the third embodiment brings about the same advantageous effects as those of the configuration of the first embodiment.

### 4. Modification, etc

In the foregoing embodiments, both ends of the bonding wire 51 are coupled to the same electrode, but this is not a limitation. For example, one end of the bonding wire 51 may be coupled to the pad 21A and the other end may be coupled to the electrode 72. Alternatively, one end of the bonding wire 51 may be coupled to the pad 21A and the other end may be coupled to the pad 21B. It is sufficient that the height position H2 of the upper end of the bonding wire 51 (conductor) functioning as an external extraction electrode is higher than the other conductive members and the upper end is not exposed to the outside of the package member 60.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate including a first electrode, the first electrode being provided on a first surface of the substrate toward a first direction;
a first semiconductor chip provided on the first surface and including a first pad electrically coupled to the first electrode;
a second semiconductor chip provided on the first surface and including a second pad electrically coupled to the first electrode;
a resin provided on the first surface of the substrate to cover the first semiconductor chip and the second semiconductor chip; and
a conductor having a bent portion projecting upward from the first electrode, one end of the conductor being coupled to the first electrode, the conductor being isolated from other conductors excluding the first electrode, and the bent portion being covered with the resin.

2. The semiconductor device of claim 1, wherein the conductor is a bonding wire whose other end is coupled to the first electrode.

3. The semiconductor device of claim 1, wherein a plurality of the conductors extend in the first direction and are provided on the first electrode.

4. The semiconductor device of claim 1, further comprising:
a first bonding wire which couples the first pad and the first electrode in the resin; and
a second bonding wire which couples the second pad and the first electrode in the resin,
wherein a height position of an upper end of the conductor toward the first direction is higher than a height position of an upper end of each of the first bonding wire and the second bonding wire and is lower than a second surface of the resin toward the first direction.

5. The semiconductor device of claim 1, further comprising a semiconductor package provided on the first surface in the resin and including a first terminal, a second terminal, a third terminal, and a fourth terminal, the first terminal being coupled to the first electrode,
wherein the substrate includes:
a first die pad which is provided on the first surface and to which a third pad of the first semiconductor chip is coupled;
a second die pad which is provided on the first surface and to which a fourth pad of the second semiconductor chip is coupled;
a second electrode which is provided on the first surface and to which a fifth pad of the first semiconductor chip, a sixth pad of the second semiconductor chip, and the second terminal of the semiconductor package are coupled;
a third electrode which is provided on the first surface and to which the third terminal of the semiconductor package is coupled; and
a fourth electrode which is provided on the first surface and to which the fourth terminal of the semiconductor package is coupled.

6. The semiconductor device of claim 5, wherein:
the semiconductor package includes a light emitting element and a light receiving element;
the first terminal and the second terminal are coupled to the light receiving element; and
the third terminal and the fourth terminal are coupled to the light emitting element.

7. The semiconductor device of claim 1, wherein:
the first semiconductor chip and the second semiconductor chip each include a transistor;
the first pad is source of the transistor of the first semiconductor chip; and
the second pad is source of the transistor of the second semiconductor chip.

8. The semiconductor device of claim 1, wherein of the bent portion of the conductor, a portion that is farthest from the first electrode is covered with the resin.

9. A semiconductor device comprising:
a substrate including a first electrode, the first electrode being provided on a first surface of the substrate toward a first direction;
a first semiconductor chip provided on the first surface and including a first pad electrically coupled to the first electrode;
a second semiconductor chip provided on the first surface and including a second pad electrically coupled to the first electrode;
a resin provided on the first surface of the substrate to cover the first semiconductor chip and the second semiconductor chip; and
a second conductor and a third conductor which are formed on the first electrode and which have a columnar shape extending upward.
